(19) United States
(12) Patent Application Publication
(10) Pub. No.: US 2010/0237893 A1
(43) Pub. Date: Sep. 23, 2010

(54) SEMICONDUCTOR TEST APPARATUS AND TEST METHOD FOR SEMICONDUCTOR DEVICE

(75) Inventor: Norifumi Kobayashi, Tokyo (JP)

Correspondence Address: SPRINKLE IP LAW GROUP, 1301 W. 25TH STREET, SUITE 408, AUSTIN, TX, 78705, US

(73) Assignee: Kabushiki Kaisha Toshiba, Tokyo (JP)

(21) Appl. No.: 12/717,582

(22) Filed: Mar. 4, 2010

(30) Foreign Application Priority Data
Mar. 23, 2009 (JP) 2009-70754

(51) Int. Cl. G01R 31/26

(52) U.S. Cl. 324/765

(57) ABSTRACT

A semiconductor test apparatus comprising: a contact-resistance calculating unit that calculates contact resistance of a measuring jig using power supply current and internal voltage obtained when power supply voltage is applied; a regression-expression calculating unit that calculates a stationary time power supply current characteristic expression using the power supply current and the internal voltage obtained when the power supply voltage is applied; and a measurement-voltage calculating unit that calculates power supply voltage for a test using operating time power supply current information, which is a corresponding relation between operating time power supply current obtained when a plurality of types of power supply voltages are applied and the types of power supply voltages, the contact resistance, and the stationary time power supply current characteristic expression.

### CROSS-REFERENCE TO RELATED APPLICATIONS

This application is based upon and claims the benefit of priority from the prior Japanese Patent Application No. 2009-70754, filed on Mar. 23, 2009; the entire contents of which are incorporated herein by reference.

### BACKGROUND OF THE INVENTION

1. Field of the Invention

The present invention relates to a semiconductor test apparatus and a test method for a semiconductor device.

2. Description of the Related Art

A test for determining non-defectiveness and defectiveness of a semiconductor device such as a large scale integration (LSI) is performed during a die sorter (DS) or during a final test (FT). In the DS, a needle-like terminal of a probe card is connected to a pad of a semiconductor device formed on a wafer and voltage is applied to the semiconductor device via the needle-like terminal. In the FT, a package-sealed semiconductor device is mounted on a socket and voltage is applied to the semiconductor device via the socket.

In such a test for a semiconductor device, accurate measurement cannot be performed if contact resistance is present between a terminal of the semiconductor device and a measuring jig (a measuring terminal) included in a tester. For example, in some case, contact resistance is as high as several hundred mΩ/pin when the measuring jig and the semiconductor device are electrically connected. In such a case, power supply voltage supplied into the semiconductor device decreases because of the contact resistance. As a result, power supply voltage actually applied into a circuit of the semiconductor device is smaller than a desired value. Therefore, in some case, correct measurement of the semiconductor device cannot be performed. For example, if fluctuation of several tens millivolts occurs in measurement performed by using minimum working voltage Vmin, the semiconductor device cannot be accurately tested. Such fluctuation in voltage is affected by aged deterioration of the measuring jig and a state of contact between the measuring jig and the semiconductor device (terminal) (pressing pressure, a contact area, unevenness of a contact surface, etc.).

Therefore, in the past, the contact resistance is reduced by, for example, cleaning the measuring jig. However, in this method, long time is required for the cleaning and a performance test of the tester and the like after the cleaning. There is also a method of providing multiple pins in the semiconductor device. In this method, because the number of pads of the semiconductor device increases, useless components of the semiconductor device increase and needless measuring terminals also increase. There is also a method of monitoring internal voltage and adjusting power supply voltage and ground (GND) voltage. In this method, the internal voltage on the GND side shifts according to the adjustment of the power supply voltage. Therefore, repetition of the voltage adjustment and check of the internal voltage monitoring occurs to make the voltage adjustment complicated. If the internal voltage is monitored and fed back to the tester to adjust the internal voltage to be constant, oscillation occurs in the circuit in the semiconductor device and breaks the tester and the semiconductor device (a device).

As a method of reducing the contact resistance, in the inspection method disclosed in Japanese Patent Application Laid-Open No. 2003-172763, forward direction resistance of a parasitic diode is designed such that an amount of change due to process fluctuation is sufficiently smaller than an amount of change of contact resistance between the measuring terminal and the terminal of the semiconductor device during inspection. However, such designing requires time and labor and is difficult.

### BRIEF SUMMARY OF THE INVENTION

A semiconductor test apparatus according to an embodiment of the present invention comprises: a contact-resistance calculating unit that calculates contact resistance of a measuring jig using power supply current and internal voltage obtained when power supply voltage is applied; a regression-expression calculating unit that calculates a stationary time power supply current characteristic expression using the power supply current and the internal voltage obtained when the power supply voltage is applied; and a measurement-voltage calculating unit that calculates power supply voltage for a test using operating time power supply current information, which is a corresponding relation between operating time power supply current obtained when a plurality of types of power supply voltages are applied and the types of power supply voltages, the contact resistance, and the stationary time power supply current characteristic expression.

A test method for a semiconductor device according to an embodiment of the present invention comprises: calculating, for each semiconductor device, contact resistance between the semiconductor device and a measuring jig using power supply current and internal voltage obtained when first power supply voltage is applied to the semiconductor device as a test target; calculating, for each the semiconductor device, a stationary time power supply current characteristic expression for the semiconductor device using power supply current and internal voltage obtained when second power supply voltage is applied to the semiconductor device; calculating, for each test pattern, a voltage correction value for correcting power supply voltage set for a circuit test for the semiconductor device using operating time power supply current information, which is a corresponding relation between operating time power supply current obtained when a plurality of types of power supply voltages are applied to the semiconductor device and the types of power supply voltages, the contact resistance, and the stationary time power supply current characteristic expression; calculating, for each test pattern, power supply voltage for a test used in the circuit test for the semiconductor device using the voltage correction value and the power supply voltage set for the circuit test for the semiconductor device; and performing the circuit test for the semiconductor device using the calculated power supply voltage for a test.

### BRIEF DESCRIPTION OF THE DRAWINGS

FIG. 1 is a block diagram of the configuration of a test apparatus according to an embodiment of the present invention;

FIG. 2 is a diagram for explaining contact resistance generated between an LSI and a measuring jig according to the embodiment;

FIG. 3 is a diagram for explaining types of tests executed on the LSI according to the embodiment;

FIG. 4 is a flowchart for explaining a test processing procedure for the LSI according to the embodiment;

FIG. 5 is a diagram of an example of the structure of an Iddd information table according to the embodiment;

FIGS. 6A and 6B are diagrams for explaining a method of calculating contact resistances according to the embodiment;

FIG. 7 is a diagram for explaining a method of calculating an Idds regression expression according to the embodiment; and

FIG. 8 is a diagram for explaining a method of calculating measurement voltage according to the embodiment.

### DETAILED DESCRIPTION OF THE INVENTION

Exemplary embodiments of the present invention are explained in detail below with reference to the accompanying drawings. The present invention is not limited by the embodiments.

In an embodiment of the present invention, the configuration of a semiconductor test apparatus (a test apparatus 1 explained later) for testing a semiconductor device (an LSI, etc.) is explained. Then, a procedure of test processing for the LSI by the test apparatus 1 is explained.

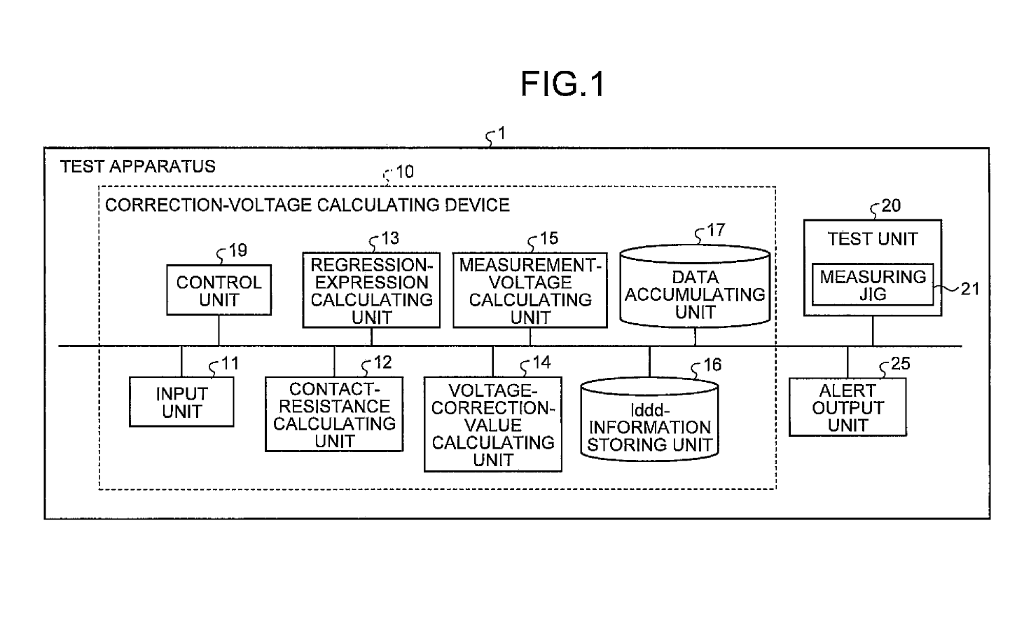

FIG. 1 is a block diagram of the configuration of the test apparatus 1 according to this embodiment. The test apparatus 1 is an apparatus that determines non-defectiveness and defectiveness of a semiconductor device such as an LSI. The test apparatus 1 includes a test unit 20, an alert output unit 25, and a correction-voltage calculating device 10 as one of characteristics of this embodiment.

The test apparatus 1 according to this embodiment compensates for power supply voltage in measurement of an LSI (an LSI 30 explained later) according to the following processing of (1) to (3):

(1) measuring consumed current while changing the power supply voltage to calculate contact resistances on a power supply side and a GND side;
(2) preparing a table indicating dependency of the consumed current on a test pattern; and
(3) calculating a voltage correction value (a power supply voltage correction value) corresponding to the contact resistance and the test pattern and calculating measurement voltage used during a test.

The voltage correction value in this embodiment is a correction value for correcting power supply voltage used in measuring the LSI 30. The voltage correction value is calculated for each of types of tests (DS1, FT1, etc. explained later), each of test patterns (tests A and B, etc. explained later), and each of LSIs (chips) 30.

The test unit 20 includes a measuring jig 21. The test unit 20 electrically connects the LSI 30 as a measurement target and the measuring jig 21 to perform a test for the LSI 30. The measuring jig 21 is, for example, a probe card or a socket. When the LSI 30 is provided on a wafer, the LSI 30 is tested by the test apparatus 1 including the probe card. When the LSI 30 is package-sealed, the LSI 30 is tested by the test apparatus 1 including the socket. The test apparatus 1 can be separate apparatuses such as the test apparatus 1 including the probe card and the test apparatus 1 including the socket or can be an apparatus including both the probe card and the socket.

The test unit 20 according to this embodiment measures, based on an instruction from the correction-voltage calculating device 10, power supply currents (power supply currents I1 to I4 explained later) and internal voltages (internal voltages Vv1, Vv2, Vg1, and Vg2 explained later) used in calculating contact resistances (contact resistances Rv and Rg explained later). The test unit 20 applies two-condition voltages (power supply voltages V1 and V2 explained later) to the LSI 30 as, for example, power supply voltage (VDD) for contact resistance calculation (first power supply voltage) and measures power supply current for contact resistance calculation and internal voltage for contact resistance calculation.

The test unit 20 according to this embodiment measures, based on an instruction from the correction-voltage calculating device 10, power supply currents (power supply currents Imin, Ityp, and Imax explained later) and internal voltages (internal voltages Vmin, Vtyp, and Vmax explained later) used in calculating a voltage correction value. The test unit 20 applies three types of voltages to the LSI 30 as, for example, power supply voltage for correction value calculation (second power supply voltage) and measures power supply current for correction value calculation and internal voltage for correction value calculation.

The test unit 20 according to this embodiment measures, for each of the types of the tests and for each of the LSIs 30, power supply current for contact resistance calculation, internal voltage for contact resistance calculation, power supply current for correction value calculation, and internal voltage for correction value calculation. The test unit 20 sends a measurement result to the correction-voltage calculating device 10.

The alert output unit 25 is connected to the test unit 20 and the correction-voltage calculating device 10 and outputs an alert according to an alert output instruction from the correction-voltage calculating device 10. The alert output unit 25 performs, for example, output of sound, characters, or an image or lighting of a lamp as the output of the alert. The alert output unit 25 only has to be provided as appropriate.

The correction-voltage calculating device 10 is a device that calculates measurement voltage for a test corresponding to the contact resistances Rv and Rg of the LSI 30 and the measuring jig 21 and is connected to the test unit 20. The correction-voltage calculating device 10 includes an input unit 11, a contact-resistance calculating unit 12, a regression-expression calculating unit 13, a voltage-correction-value calculating unit 14, a measurement-voltage calculating unit 15, an Iddd-information storing unit 16, a data accumulating unit 17, and a control unit 19.

The input unit 11 receives input of calculation conditions for the contact resistances Rv and Rg and calculation conditions for a voltage correction value. The calculation conditions for the contact resistances Rv and Rg are, for example, a value of power supply voltage (power supply voltage for contact resistance calculation) applied to the LSI 30 when power supply currents and internal voltages used for calculation of the contact resistances Rv and Rg are measured. The calculation conditions for the voltage correction value are, for example, a value of power supply voltage (power supply voltage for correction value calculation) applied to the LSI 30 when power supply currents and internal voltages used for calculation of the voltage correction value are measured. A measurement result is input to the input unit 11 from the test unit 20.

The input unit 11 sends the power supply voltage for contact resistance measurement and the power supply voltage for correction value calculation to the test unit 20. The input unit 11 sends power supply currents and internal voltages obtained by applying the power supply voltage for contact resistance measurement to the LSI 30 in the measurement result, which is input from the test unit 20, to the contact-resistance calculating unit 12. The power supply voltage for contact resistance measurement and the power supply voltage for correction value calculation are not always sent from the input unit 11 to the test unit 20 and can be directly input to the test unit 20.

The contact-resistance calculating unit 12 calculates the contact resistances Rv and Rg using the power supply currents and the internal voltages obtained by applying the power supply voltage for contact resistance measurement to the LSI 30. The contact-resistance calculating unit 12 calculates the contact resistances Rv and Rg for each of the types of the tests and for each of the LSIs 30. The contact-resistance calculating unit 12 stores the calculated contact resistances Rv and Rg in the data accumulating unit 17.

The Iddd-information storing unit 16 is a memory or the like that stores a correspondence relation between a power supply voltage value and Iddd (operating time power supply current) obtained when the power supply voltage value is applied to the LSI 30 (an Iddd information table 50 explained later). In the Iddd information table (operating time power supply current information) 50, information concerning association of various power supply voltage values and Iddds obtained by applying the power supply voltage values to the LSI 30 is set for each of the test patterns. For example, when f represents a frequency, C represents a capacity, and V represents voltage, Iddd is represented as Iddd=fCV². Therefore, Iddd is a fixed value irrespectively of process fluctuation if power supply voltage is determined.

The regression-expression calculating unit (a characteristic-expression calculating unit) 13 calculates, using the power supply currents and the internal voltages obtained by applying the power supply voltage for correction value calculation to the LSI 30, an Idds regression expression (an Idds characteristic expression) (a stationary time power supply current characteristic expression). The Idds regression expression is a relational expression between the power supply current and the internal voltage. The regression-expression calculating unit 13 calculates an Idds regression expression (Idds=F(V)) for each of the types of the tests and for each of the LSIs 30. The Idds regression expression is a correspondence relation expression between stationary time power supply current and internal voltage. The Idds regression expression is obtained by subjecting, for example, the power supply currents and the internal voltages obtained by applying the power supply voltage to the LSI 30 to primary approximation, secondary approximation, or other various kinds of approximation. The regression-expression calculating unit 13 stores the calculated Idds regression expression in the data accumulating unit 17.

The voltage-correction-value calculating unit 14 calculates voltage correction values (voltage correction values ΔVv and ΔVg explained later) using the Idds regression expression stored in the data accumulating unit 17, the contact resistances Rv and Rg stored in the data accumulating unit 17, and the Iddd information table 50 stored in the Iddd-information storing unit 16. The voltage-correction-value calculating unit 14 calculates a voltage correction value for each of the types of the test and for each of the LSIs 30.

The measurement-voltage calculating unit 15 calculates, using the voltage correction values calculated by the voltage-correction-value calculating unit 14 and a desired voltage value V (power supply voltage for a test) desired to be applied to the LSI 30, voltage applied to the LSI 30 when the LSI 30 is tested (measurement value Vset). The desired voltage value V desired to be applied to the LSI 30 is set for each of the test patterns. Therefore, the measurement voltage Vset is also calculated for each of the test patterns. The measurement-voltage calculating unit 15 sends the calculated measurement voltage Vset to the test unit 20.

The data accumulating unit 17 is a memory or the like that stores, for example, the contact resistances Rv and Rg calculated by the contact-resistance calculating unit 12 and the Idds regression expression calculated by the voltage-correction-value calculating unit 14. The control unit 19 controls the input unit 11, the contact-resistance calculating unit 12, the regression-expression calculating unit 13, the voltage-correction-value calculating unit 14, the measurement-voltage calculating unit 15, the Iddd-information storing unit 16, and the data accumulating unit 17. The control unit 19 can be independently provided as in this embodiment or can be provided in the input unit 11, the contact-resistance calculating unit 12, the regression-expression calculating unit 13, the voltage-correction-value calculating unit 14, the measurement-voltage calculating unit 15, the Iddd-information storing unit 16, the data accumulating unit 17, the test unit 20, or the like.

The correction-voltage calculating device 10 includes a central processing unit (CPU), a read only memory (ROM), and a random access memory (RAM). In the correction-voltage calculating device 10, the CPU has a function of reading out, according to a user input, various control programs, application programs, and the like for correction voltage calculation (measurement voltage calculation) stored in the ROM, expanding the programs in a program storage area in the RAM, and executing various kinds of processing, temporarily storing various data generated in the processing in a data storage area formed in the RAM, and controlling the processing units of the correction-voltage calculating device 10.

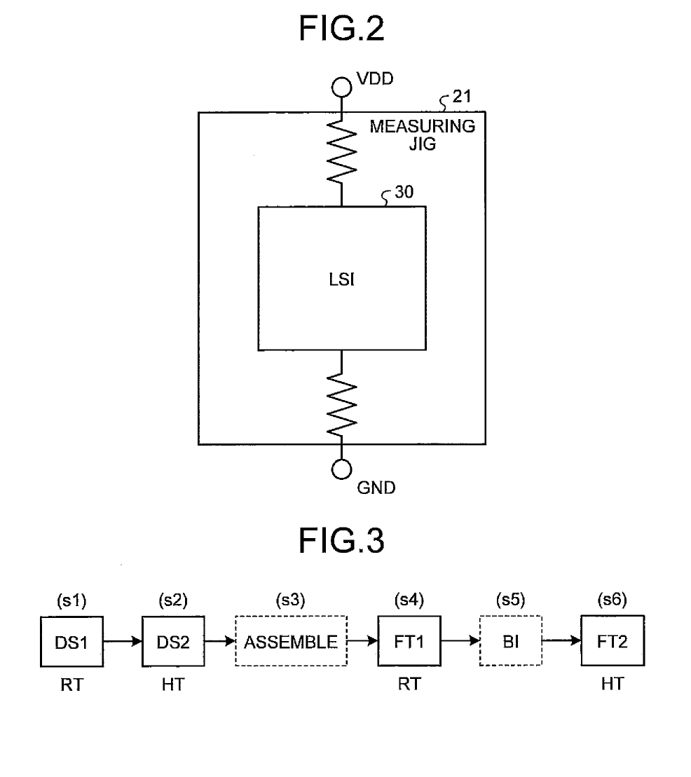

FIG. 2 is a diagram for explaining the contact resistances Rv and Rg generated between the LSI 30 and the measuring jig 21. When the contact resistances Rv and Rg are measured, the LSI 30 is connected to the measuring jig 21 of the test unit 20. The test unit 20 applies power supply voltage (represented as VDD in FIG. 2) to the LSI 30 via the measuring jig 21. Contact resistance generated between the measuring jig 21 on the power supply voltage side and the LSI 30 is the contact resistance Rv. Contact resistance generated between the measuring jig 21 on the GND side and the LSI 30 is the contact resistance Rg.

FIG. 3 is a diagram for explaining types of tests executed on the LSI 30. In FIG. 3, an example of tests executed on LSI 30 is shown.

When the formation of the LSI 30 on the wafer is completed, a test (DS1) is executed on the LSI 30 on the wafer under a room temperature environment (RT). Specifically, the LSI 30 is mounted on the probe card serving as the measuring jig 21 and a needle-like terminal of the probe card is connected to a pad of the LSI 30. Various voltages are applied to the LSI 30 via the needle-like terminal of the probe card and the DS1 (a first die sorter) is executed on the LSI 30 under the room temperature environment. In the DS1, one or a plurality of test of test patterns are executed for each of the LSIs 30 (s1).

Thereafter, the next test (DS2) is executed on the LSI 30 on the wafer under a high temperature environment (HT). Specifically, as in the DS1, the LSI 30 is mounted on the probe card serving as the measuring jig 21 and the needle-like terminal of the probe card is connected to the pad of the LSI 30. Various voltages are applied to the LSI 30 via the needle-like terminal of the probe card and the DS2 (a second die sorter) is executed on the LSI 30 under the high temperature environment. In the DS2, one or a plurality of test of test patterns are executed for each of the LSIs 30 (s2).

Thereafter, the LSIs 30 are separated from the wafer and package-sealed, whereby assembly processing for the LSI 30 is performed (s3). A test (TF1) is executed on the package-sealed LSI 30 under the room temperature environment (RT). Specifically, the package-sealed LSI 30 is mounted on the socket serving as the measuring jig 21. Various voltages are applied to the LSI 30 via the socket and the FT1 (a first final test) is executed on the LSI 30 under the room temperature environment. In the FT1, one or a plurality of test of test patterns are executed for each of the LSIs 30 (s4).

Thereafter, BI (burn in) is applied to the package-sealed LSI 30. Specifically, the package-sealed LSI 30 is placed under the high temperature environment for a predetermined time (s5). Thereafter, a test (FT2) is executed on the package-sealed LSI 30 under the high temperature environment (HT). Specifically, the package-sealed LSI 30 is mounted on the socket serving as the measuring jig 21. Various voltages are applied to the LSI 30 via the socket and the FT2 (a second final test) is executed on the LSI 30. In the FT2, one or a plurality of test of test patterns are executed for each of the LSIs 30 (s6).

The DS1, the DS2, the FT1, and the FT2 are examples of the tests executed on the LSI 30. The tests executed on the LSI 30 are not limited to the order and the types of the tests shown in FIG. 3. Tests of types different from the tests shown in FIG. 3 can be performed or the tests can be performed in order different from the order of the tests shown in FIG. 3.

As test processing for the LSI 30, first, the DS1 is performed. In the D51, the test apparatus 1 connects the needle-like terminal to a first LSI 30 and executes a test on the first LSI 30 with a first test pattern. When the test with the first test pattern is completed, the test apparatus 1 executes a test with the next test pattern. The test apparatus 1 executes all test patterns performed in the DS1 on the first LSI 30 by repeating processing for, after executing a test with an nth (n is a natural number) test pattern, executing a test with a (n+1)th test pattern.

After executing all the test of test patterns on the first LSI 30, the test apparatus 1 removes the needle-like terminal from the first LSI 30 and connects the needle-like terminal to a second LSI 30. The test apparatus 1 executes all the test of test patterns on the second LSI 30 in the same manner as the test of test patterns executed on the first LSI 30. The test apparatus 1 executes all tests performed in the DS1 on all the LSIs 30 on the wafer by repeating, after executing the test on an mth (m is a natural number) LSI 30 with all the test patterns, executing the tests with all the test patterns on a (m+1)th LSI 30.

Thereafter, the test apparatus 1 executes all tests executed in the DS2 on all the LSIs 30 on the wafer according to a processing procedure same as that in the DSI. The test apparatus 1 executes all tests performed in the FT1 and the FT2 on the package-sealed LSI 30 according to the processing procedure same as that in the DS1.

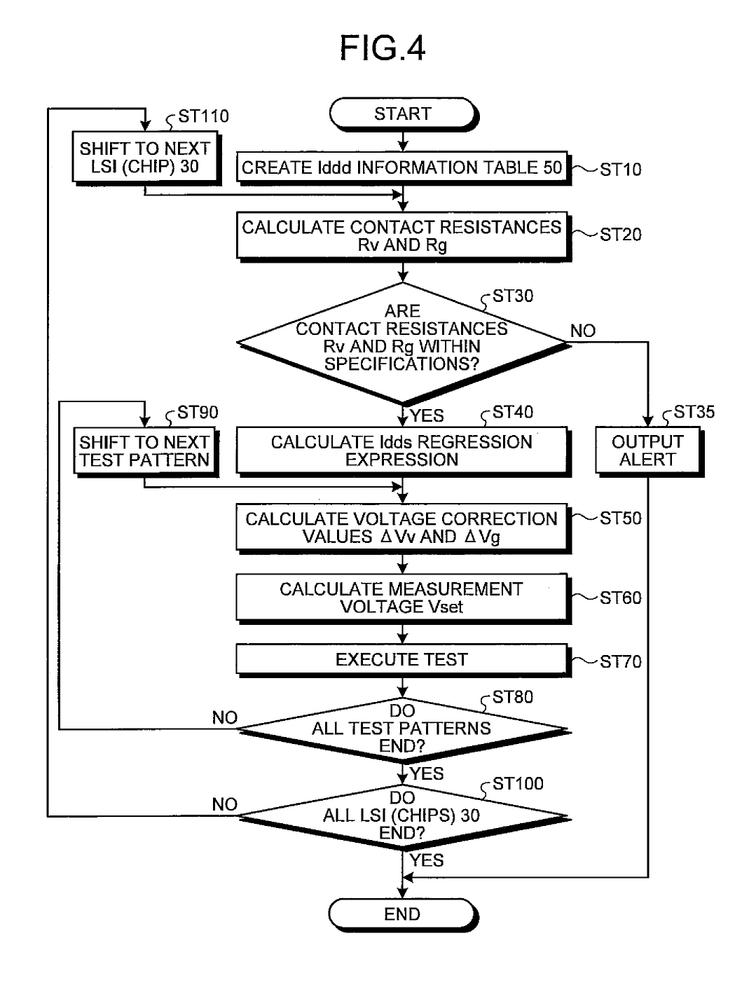

FIG. 4 is a flowchart of a test processing procedure for an LSI according to this embodiment. In FIG. 4, a test processing procedure in performing one test (any one of the DS1, DS2, FT1, and FT2) is shown. The Iddd information table 50 is stored in advance in the Iddd-information storing unit 16 of the test apparatus 1 (step ST10).

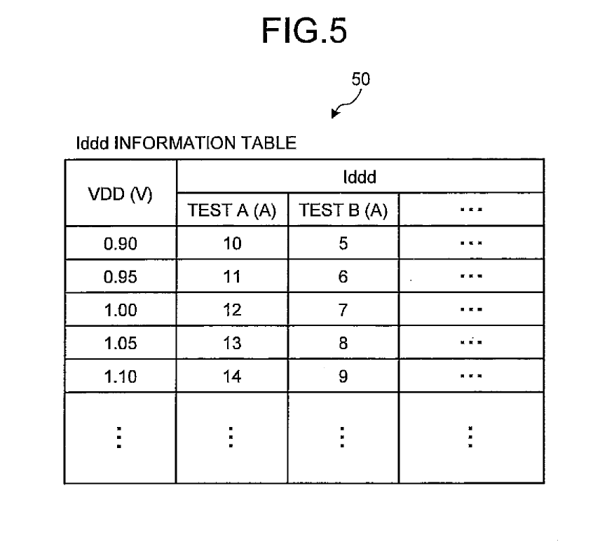

FIG. 5 is a diagram of an example of the structure of the Iddd information table 50. In the Iddd information table 50, power supply voltage and Iddd are associated with each other for each of power supply voltages and for each of test patterns. The test patterns registered in the Iddd information table 50 include test patterns peculiar to types of tests and a test pattern common to types of a plurality of tests. Therefore, the Iddd information table 50 includes a test pattern used only for the DS1 and a test pattern used for both the DS1 and the FT1.

In the example shown in FIG. 5, the test patterns registered in the Iddd information table 50 are a test pattern A and a test pattern B. In the case of the Iddd information table 50 shown in FIG. 5, for example, if 0.90 volt is applied to the LSI 30 as power supply voltage when the test pattern A is performed, the Iddd is 10 amperes.

After the Iddd information table 50 is stored in the Iddd-information storing unit 16, the test unit 20 measures, for each of the types of the tests and for each of the LSIs 30, power supply current for contact resistance calculation, internal voltage for contact resistance calculation, power supply current for correction value calculation, and internal voltage for correction value calculation. When the internal voltages are measured, for example, it is desirable to perform IDDS measurement such that the internal voltages can be measured with an internal circuit set in as calm and stable a condition as possible. The IDDS measurement means internal voltage measurement performed when the LSI 30 is in a standby state (a stationary state) (stationary time power supply current measurement). The test unit 20 sends the power supply current for contact resistance calculation and the internal voltage for contact resistance calculation to the contact-resistance calculating unit 12. The test unit 20 sends the power supply current for correction value calculation and the internal voltage for correction value calculation to the regression-expression calculating unit 13.

The contact-resistance calculating unit 12 calculates the contact resistances Rv and Rg using power supply currents and internal voltages obtained by applying the power supply voltage for contact resistance measurement to the LSI 30.

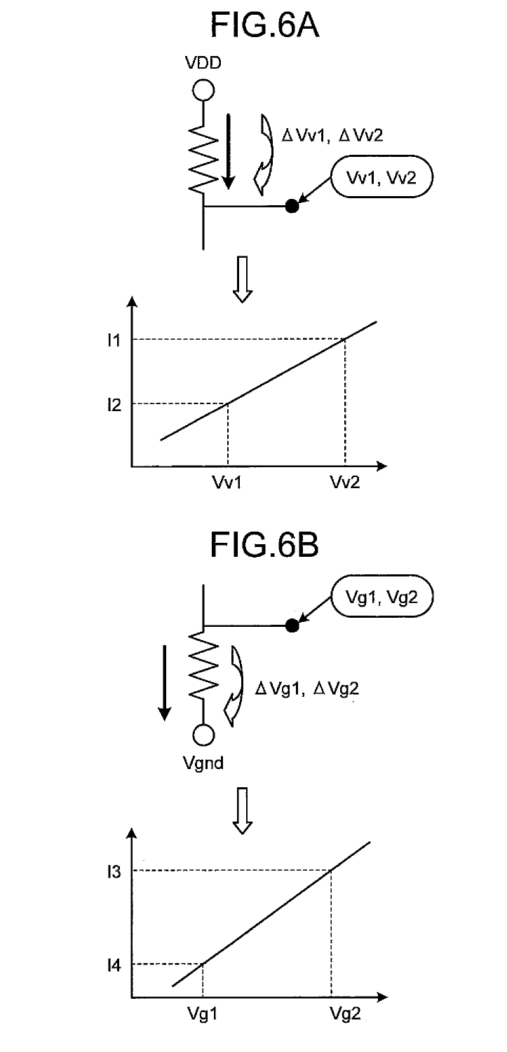

FIGS. 6A and 6B are diagrams for explaining a method of calculating the contact resistances Rv and Rg. As shown in FIG. 6A, to calculate the contact resistance Rv on a power supply side (a VDD side), the test unit 20 applies power supply voltage V1 and power supply voltage V2 to the LSI 30 from the power supply side. Consequently, the test unit 20 obtains internal voltages Vv1 and Vv2 and power supply currents I1 and 12 as a measurement result.

The contact-resistance calculating unit 12 calculates drop voltages ΔVv1 and ΔVv2 due to the contact resistance Rv using the internal voltages Vv1 and Vv2. Specifically, the contact-resistance calculating unit 12 calculates the drop voltages ΔVv1 and ΔVv2 using Formula (1) and Formula (2) and calculates the contact resistance Rv using Formula (3).

ΔVv1=V1−Vv1 (1)

ΔVv2=V2−Vv2 (2)

Rv=(ΔVv1−ΔVv2)/(I1−i2) (3)

As shown in FIG. 6B, to calculate the contact resistance Rg on a GND side (Vgnd), the test unit 20 applies the power supply voltage V1 and the power supply voltage V2 to the LSI 30 from the GND side. Consequently, the test unit 20 obtains internal voltages Vg1 and Vg2 and power supply currents I3 and I4 as a measurement result.

The contact-resistance calculating unit 12 calculates drop voltages ΔVg1 and ΔVg2 due to the contact resistance Rg using the internal voltages Vg1 and Vg2 and GND voltage Vgnd. Specifically, the contact-resistance calculating unit 12 calculates the drop voltages ΔVg1 and ΔVg2 using Formula (4) and Formula (5) and calculates the contact resistance Rg using Formula (6) (step ST20).

ΔVg1=Vg1−Vgnd (4)

ΔVg2=Vg2−Vgnd (5)

Rg=(ΔVg1−ΔVg2)/(I3−I4) (6)

The drop voltages ΔVv1, ΔVv2, ΔVg1, and ΔVg2 change according to a connection state between the LSI 30 and the measuring jig 21. Therefore, the contact-resistance calculating unit 12 calculates the drop voltages ΔVv1, ΔVv2, ΔVg1, and ΔVg2 for each of the LSIs 30 to be tested. In this processing, the contact-resistance calculating unit 12 calculates the drop voltages ΔVv1, ΔVv2, ΔVg1, and ΔVg2 corresponding to the first LSI 30 to be tested.

The control unit 19 determines whether the calculated contact resistances Rv and Rg are within specifications (step ST30). When the calculated contact resistances Rv and Rg are outside the specifications (“No” at step ST30), the test apparatus 1 outputs an alert (step ST35) and ends the test processing. When the test apparatus 1 outputs the alert, the control unit 19 instructs the alert output unit 25 to output the alert. The alert output unit 25 outputs the alert according to the instruction of the control unit 19.

When the calculated contact resistances Rv and Rg are within the specifications (“Yes” at step ST30), the contact-resistance calculating unit 12 stores the calculated contact resistances Rv and Rg in the data accumulating unit 17. The regression-expression calculating unit 13 calculates an Idds regression expression using the power supply currents and the internal voltages obtained by applying the power supply voltage for correction value calculation to the LSI 30.

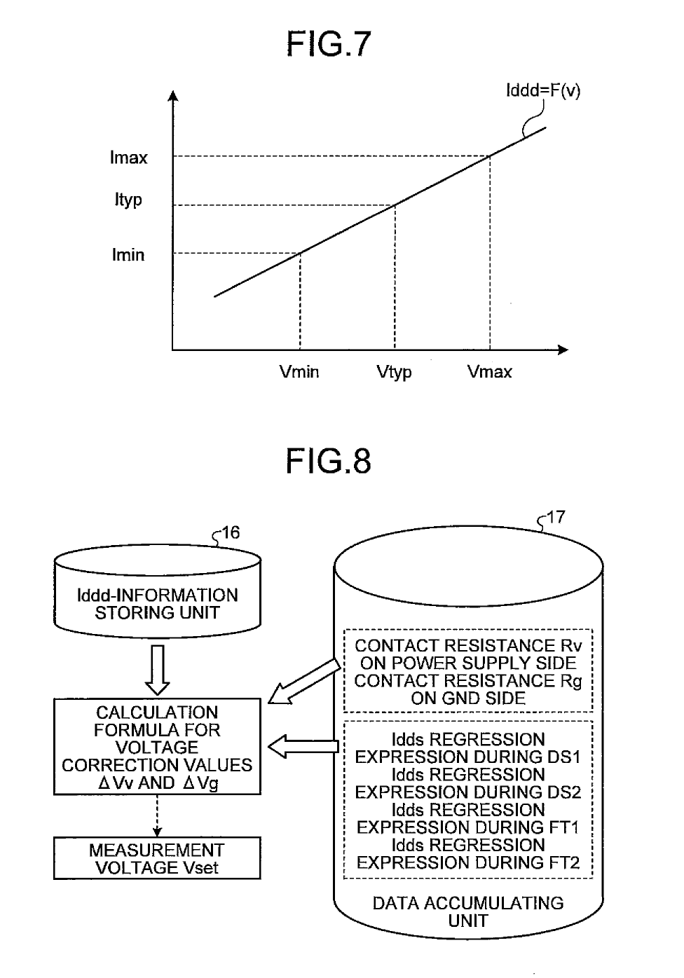

FIG. 7 is a diagram for explaining a method of calculating the Idds regression expression. As shown in FIG. 7, to calculate the Idds regression expression, the test unit 20 applies three types of power supply voltages to the LSI 30 as power supply voltage and measures the power supply current Imin, Ityp, and Imax and the internal voltages Vmin, Vtyp, and Vmax. The three types of voltages applied to the LSI 30 by the test unit 20 are, for example, power supply voltages (two types) for contact resistance calculation and one type of power supply voltage different from the power supply voltages.

The regression-expression calculating unit 13 calculates the Idds regression expression using the power supply current Imin and the internal voltage Vmin, the power supply current Ityp and the internal voltage Vtyp, and the power supply current Imax and the internal voltage Vmax. The internal voltage Vmin, the internal voltage Vtyp, and the internal voltage Vmax are values calculated according to Vv-Vg. The regression-expression calculating unit 13 applies predetermined approximation to the power supply currents Imin, Ityp, and Imax and the internal voltages Vmin, Vtyp, and Vmax measured by the test unit 20 to thereby calculate Idds=F(v) as the Idds regression expression (step ST40). The regression-expression calculating unit 13 stores the calculated Idds regression expression in the data accumulating unit 17.

The voltage-correction-value calculating unit 14 calculates voltage correction values ΔVv and ΔVg using the Idds regression expression stored in the data accumulating unit 17, the contact resistances Rv and Rg stored in the data accumulating unit 17, and the Iddd information table 50 stored in the Iddd-information storing unit 16. The voltage-correction-value calculating unit 14 extracts Iddd corresponding to the test patterns from the Iddd information table 50 and calculates the voltage correction values ΔVv and ΔVg using the extracted Iddd. Specifically, The voltage-correction-value calculating unit 14 calculates the voltage correction value ΔVv using Formula (7) and calculates the voltage correction value ΔVg using Formula (8) (step ST50).

ΔVv=Rvx(Idds+Iddd) (7)

ΔVg=Rgx(Idds+Iddd) (8)

The voltage correction values ΔVv and ΔVg include the Iddd and are calculated for each of the test patterns. The measurement-voltage calculating unit 15 calculates, using the voltage correction values ΔVv and ΔVg calculated by the voltage-correction-value calculating unit 14 and the desired voltage value V desired to be applied to the LSI 30, voltage applied to the LSI 30 when the LSI 3 is tested (measurement voltage Vset). Specifically, the measurement-voltage calculating unit 15 calculates the measurement voltage Vset using Formula (9) (step ST60).

Vset=V+ΔVv+ΔVg (9)

The measurement voltage Vset can be represented as Formula (10) and Formula (11) according to Formula (7) to Formula (9).

Vset=V+(Rvx(Idds+Iddd))+(Rgx(Idds+Iddd)) (10)

Vset=V+(Rvx(F(v)+Iddd))+(Rgx(F(v)+Iddd)) (11)

The measurement voltage Vset includes the Iddd and is measured for each of the test patterns. In this processing, the measurement-voltage calculating unit 15 calculates the measurement voltage Vset corresponding to a test pattern performed first.

FIG. 8 is a diagram for explaining a method of calculating the measurement voltage Vset. The Iddd information table 50 is stored in the Iddd-information storing unit 16 in advance. When the test apparatus 1 starts a test of the LSI 300, the contact resistance Rv on the power supply side and the contact resistance Rg on the GND side calculated by the contact-resistance calculating unit 12 are stored in the data accumulating unit 17. The contact resistances Rv and Rg corresponding to the LSIs 30 are stored in the data accumulating unit 17 for each of the types of the tests.

The Idds regression expression calculated by the regression-expression calculating unit 13 is stored in the data accumulating unit 17. When the DS1 is performed, the Idds regression expression used in the DS1 is stored in the data accumulating unit 17. When the DS2 is performed, the Idds regression expression used in the DS2 is stored in the data accumulating unit 17. When the FT1 is performed, the Idds regression expression used in the FT1 is stored in the data accumulating unit 17. When the FT2 is performed, the Idds regression expression used in the FT2 is stored in the data accumulating unit 17.

The voltage-correction-value calculating unit 14 calculates the voltage correction values ΔVv and ΔVg using Formula (7) and Formula (8) as the calculation formulas for the voltage correction values ΔVv and ΔVg, the Idds regression expression stored in the data accumulating unit 17, and the Iddd information table 50 stored in the Iddd-information storing unit 16. The measurement-voltage calculating unit 15 calculates, using the voltage correction values ΔVv and ΔVg calculated by the voltage-correction-value calculating unit 14, the measurement voltage Vset applied to the LSI 30 when the LSI 30 is tested.

Thereafter, the measurement-voltage calculating unit 15 sends the calculated measurement voltage Vset to the test unit 20. The test unit 20 executes a test on the LSI 30 of a first chip with a first test pattern using the measurement voltage Vset (step ST70). The test unit 20 tests the LSI 30 of the first chip using the measurement voltage Vset corresponding to the first test pattern. When the test is completed, the control unit 19 of the correction-voltage calculating device 10 checks whether all the test of test patterns are executed on the LSI 30 of the first chip (step ST80). When all the test of test patterns are not executed on the LSI 30 of the first chip (“No” at step ST80), the control unit 19 shifts to the next test pattern (step ST90).

Specifically, the voltage-correction-value calculating unit 14 calculates the voltage correction values ΔVv and ΔVg using the Idds regression expression stored in the data accumulating unit 17, the contact resistances Rv and Rg stored in the data accumulating unit 17, and the Iddd information table 50 stored in the Iddd-information storing unit 16. The voltage-correction-value calculating unit 14 extracts Iddd corresponding to a second test pattern from the Iddd information table 50 and calculates the voltage correction values ΔVv and ΔVg using the extracted Iddd. The voltage-correction-value calculating unit 14 calculates the voltage correction value ΔVv using Formula (7) and calculates the voltage correction value ΔVg using Formula (8) (step ST50).

The measurement-voltage calculating unit 15 calculates the measurement voltage Vset using the voltage correction values ΔVv and ΔVg corresponding to the next test pattern and the desired voltage value V desired to be applied to the LSI 30 when the next test of test pattern (the second test pattern) is executed. The measurement-voltage calculating unit 15 calculates the measurement voltage Vset using Formula (9) (step ST60). In this processing, the measurement-voltage calculating unit 15 calculates the measurement voltage Vset corresponding to the test pattern performed second.

The measurement-voltage calculating unit 15 sends the calculated measurement voltage Vset to the test unit 20. The test unit 20 executes a test on the LSI 30 of the first chip with the second test pattern using the measurement voltage Vset (step ST70). The test unit 20 tests the LSI 30 of the first chip using the measurement voltage Vset corresponding to the second test pattern. When the test is completed, the control unit 19 of the correction-voltage calculating device 10 checks whether all the test of test patterns are executed on the LSI 30 of the first chip (step ST80).

The processing at steps ST90 and steps ST50 to ST80 is repeated until all the test of test patterns are executed on the LSI 30 of the first chip. When all the test patterns are executed on the LSI 30 of the first chip (“Yes” at step ST80), the control unit 19 checks whether tests of all the LSIs 30 are executed (step ST100).

When the tests of all the LSIs 30 are not executed (“No” at step ST100), the control unit 19 shifts to a test of the next LSI 30 (an LSI of a second chip) (step ST100). The test apparatus 1 executes the test of the LSI 30 of the second chip according to processing same as that for the LSI 30 of the first chip (steps ST20 to ST100).

When all the test of test patterns are executed on the LSI 30 of the second chip (“Yes” at step ST80), the control unit 19 checks whether tests of all the LSIs 30 are executed (step ST100). When the tests of all the LSIs 30 are not executed (“No” at step ST100), the processing at step ST110 and steps ST20 to ST100 is repeated until the tests of all the LSIs 30 are executed. Test results of the LSIs 30 are stored in the data accumulating unit 17 or the like. When the tests of all the LSIs 30 are executed (“Yes” at step ST100), the test apparatus 1 ends the test processing.

In the flowchart shown in FIG. 4, the measurement voltage Vset is calculated by using the desired voltage value V desired to be applied to the LSI 30. However, the measurement voltage Vset corresponding to a minimum or a maximum of motion-compensated power supply voltage can be calculated. When working voltage corresponding to the ability of each of the LSIs 30 is designated for the LSI 30, the measurement voltage Vset can be calculated according to working voltages (VID) of the LSIs 30. In this case, as in the case explained above, the measurement voltage Vset corresponding to a minimum or a maximum of power supply voltage motion-compensated by the VID can be calculated.

When internal voltage is monitored and corrected as in the related art, because a current value is different for each of the test patterns, voltage is also different. To correct the influence of the difference in voltage, processing such as internal monitoring (measurement) of applied voltage, adjustment (correction) of the applied voltage, and check of the internal monitoring is necessary. Therefore, repetition of the voltage adjustment and the check of internal voltage monitoring occurs and test time increases. In the method in the past, when the power supply voltage (Vdd) is determined, it is necessary to monitor the internal voltage on the Vdd side and the internal voltage on the GND side and adjust applied voltage. On the other hand, the test apparatus 1 according to this embodiment can easily calculate appropriate power supply voltage for each of the LSIs 30 and for each of the test patterns and apply the power supply voltage to the LSIs 30. Correction of the contact resistance Rg on the GND side can also be centrally managed.

Even when working voltage is designated for each of the LSTs 30, applied voltage corresponding to the operation voltages (VID) of the LSIs 30 can be easily set. In the case of the method in the past, the calculation of applied voltage corresponding to the VID is extremely complicated because the repetition of voltage adjustment and check of internal voltage monitoring occurs. However, in the case of this embodiment, the repetition of voltage adjustment and check of internal voltage monitoring does not occur. Therefore, the applied voltage corresponding to the VID can be set in a short time by using the Iddd information table 50.

The correction-voltage calculating device 10 has the function of determining whether the calculated contact resistances Rv and Rg are within the predetermined specifications and, when the contact resistances Rv and Rg are not within the predetermined specifications, issuing an alert output instruction (the control unit 19). The test apparatus 1 includes the alert output unit 25 that outputs an alert according to the alert output instruction from the correction-voltage calculating device 10. Because the correction-voltage calculating device 10 directly calculates the contact voltages Rv and Rg, the correction-voltage calculating device 10 can cause the alert output unit 25 to output an alert for abnormality of measurement environment (deterioration of the needle-like terminal, etc.). Consequently, when measurement abnormality occurs, mass production stop measures or the like can be taken. The test apparatus 1 determines and accumulates the Idds regression expression every time a test is performed. Therefore, if unexpected abnormality occurs, the test apparatus 1 can easily detect the abnormality and outputs an alert.

In this embodiment, the test apparatus 1 includes the correction-voltage calculating device 10. However, the correction-voltage calculating device 10 can be provided separately from the test apparatus 1. In this embodiment, the correction-voltage calculating device 10 includes the Iddd-information storing unit 16 and the data accumulating unit 17. However, the Idds-information storing unit 16 and the data accumulating unit 17 can be included in a device other than the correction-voltage calculating device 10.

The processing for storing the Iddd information table 50 in the Iddd-information storing unit 16, the processing for calculating the contact resistances Rv and Rg, and the processing for calculating the Idds regression expression can be performed at any timing and in any order as long as these kinds of processing are performed before the calculation of the voltage correction values ΔVv and ΔVg.

In this embodiment, the contact resistances Rv and Rg are calculated by using the two types of power supply voltages. However, the contact resistances Rv and Rg can be calculated by using one type or three or more types of power supply voltages. In this embodiment, the Idds regression expression is calculated by using the three types of power supply voltages. However, the Idds regression expression can be calculated by using two types or four or more types of power supply voltages.

In the embodiment explained above, for convenience of explanation, the contact resistance unit 12, the regression-expression calculating unit 13, the voltage-correction-value calculating unit 14, and the measurement-voltage calculating unit 15 are explained as separate blocks. However, the present invention is not limited to this. Therefore, all the functions of these units can be performed by one block. Functions of a plurality of blocks can be performed by one block. For example, the voltage-correction-value calculating unit 14 can be built in the measurement-voltage calculating unit 15.

As explained above, according to the embodiment, because the voltage correction values ΔVv and Δvg are calculated by using the Idds regression expression, the contact resistances Rv and Rg, and the Iddd information table 50, the voltage correction values ΔVv and ΔVg corresponding to the contact resistances Rv and Rg can be easily calculated. Therefore, it is possible to easily perform a circuit test corresponding to the contact resistances Rv and Rg.

(Note) A test apparatus including: a measurement-voltage calculating unit that calculates contact resistance between a semiconductor device and a measuring jig and calculates, based on a result of the calculation, for each the semiconductor device, power supply voltage for a test used in a circuit test for the semiconductor device; a test unit that performs the circuit test for the semiconductor device using the calculated power supply voltage for a test; and an alert output unit that outputs an alert when the contact voltage is not within a predetermined range.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor test apparatus comprising:
a contact-resistance calculating unit that calculates contact resistance of a measuring jig using power supply current and internal voltage obtained when power supply voltage is applied;
a regression-expression calculating unit that calculates a stationary time power supply current characteristic expression using the power supply current and the internal voltage obtained when the power supply voltage is applied; and
a measurement-voltage calculating unit that calculates power supply voltage for a test using operating time power supply current information, which is a corresponding relation between operating time power supply current obtained when a plurality of types of power supply voltages are applied and the types of power supply voltages, the contact resistance, and the stationary time power supply current characteristic expression.

2. The semiconductor test apparatus according to claim 1, wherein the contact-resistance calculating unit calculates the contact resistance of the measuring jig using power supply current and internal voltage obtained when at least one power supply voltage is applied to a semiconductor device as a test target.

3. The semiconductor test apparatus according to claim 2, wherein the contact-resistance calculating unit calculates the contact resistance for each semiconductor device.

4. The semiconductor test apparatus according to claim 1, wherein the regression-expression calculating unit calculates the stationary time power supply current characteristic expression using power supply current and internal voltage obtained when at least two power supply voltages are applied to a semiconductor device as a test target.

5. The semiconductor test apparatus according to claim 4, wherein the regression-expression calculating unit calculates the stationary time power supply current characteristic expression for each semiconductor device.

6. The semiconductor test apparatus according to claim 1, wherein the measurement-voltage calculating unit includes a voltage-correction-value calculating unit that calculates, for each test pattern, a voltage correction value for correcting a power supply voltage set for a circuit test for a semiconductor device as a test target using the operating time power supply current information, the contact resistance, and the stationary time power supply current characteristic expression.

7. The semiconductor test apparatus according to claim 1, wherein the measurement-voltage calculating unit includes a voltage-correction-value calculating unit that calculates, for each semiconductor device, a voltage correction value for correcting power supply voltage set for a circuit test for a semiconductor device as a test target using the operating time power supply current information, the contact resistance, and the stationary time power supply current characteristic expression.

8. The semiconductor test apparatus according to claim 6, wherein the measurement-voltage calculating unit calculates, for each test pattern, power supply voltage for a test used in the circuit test for the semiconductor device using the voltage correction value and the power supply voltage set for the circuit test for the semiconductor device.

9. The semiconductor test apparatus according to claim 7, wherein the measurement-voltage calculating unit calculates, for each semiconductor device, power supply voltage for a test used in the circuit test for the semiconductor device using the voltage correction value and the power supply voltage set for the circuit test for the semiconductor device.

10. The semiconductor test apparatus according to claim 1, further comprising a storing unit that stores the operating time power supply current information for each type of a test pattern of the circuit test, wherein
the voltage-correction-value calculating unit extracts the operating time power supply current information corresponding to the test pattern from the storing unit and calculates the voltage correction value corresponding to the test pattern using the extracted operating time power supply current information.

11. The semiconductor test apparatus according to claim 1, further comprising an alert output unit that outputs an alert when the contact resistance is not within a predetermined range.

12. The semiconductor test apparatus according to claim 6, wherein power supply voltage set for the circuit test is a minimum or a maximum of motion-compensated power supply voltage.

13. The semiconductor test apparatus according to claim 1, wherein power supply voltage set for a circuit test is power supply voltage corresponding to operation voltage for each the semiconductor device set according to ability of the semiconductor device.

14. A test method for a semiconductor device comprising:
calculating, for each semiconductor device, contact resistance between the semiconductor device and a measuring jig using power supply current and internal voltage obtained when first power supply voltage is applied to the semiconductor device as a test target;
calculating, for each the semiconductor device, a stationary time power supply current characteristic expression for the semiconductor device using power supply current and internal voltage obtained when second power supply voltage is applied to the semiconductor device;
calculating, for each test pattern, a voltage correction value for correcting power supply voltage set for a circuit test for the semiconductor device using operating time power supply current information, which is a corresponding relation between operating time power supply current obtained when a plurality of types of power supply voltages are applied to the semiconductor device and the types of power supply voltages, the contact resistance, and the stationary time power supply current characteristic expression;
calculating, for each test pattern, power supply voltage for a test used in the circuit test for the semiconductor device using the voltage correction value and the power supply voltage set for the circuit test for the semiconductor device; and
performing the circuit test for the semiconductor device using the calculated power supply voltage for a test.

15. The test method for a semiconductor device according to claim 14, further comprising:
storing, for each type of a test pattern of the circuit test, the operating time power supply current information in a storing unit before calculating the voltage correction value; and
extracting, in calculating the voltage correction value, the operating time power supply current information corresponding to the test pattern from the storing unit and calculating the voltage correction value corresponding to the test pattern using the extracted operating time power supply current information.

16. The test method for a semiconductor device according to claim 14, further comprising outputting an alert when the contact resistance is not within a predetermined range.

17. The test method for a semiconductor device according to claim 14, wherein the power supply voltage set for the circuit test is a minimum or maximum of motion-compensated power supply voltage.

18. The test method for a semiconductor device according to claim 14, wherein the power supply voltage set for the circuit test is power supply voltage corresponding to operation voltage for each the semiconductor device set according to ability of the semiconductor device.

19. The test method for a semiconductor device according to claim 14, wherein the first power supply voltage is a plurality of types of power supply voltage values.

20. The test method for a semiconductor device according to claim 14, wherein the stationary time power supply current characteristic expression is calculated by using the first power supply voltage and the second power supply voltage.
